(19) United States
(12) Patent Application Publication
(10) Pub. No.: US 2006/0289941 A1
(43) Pub. Date: Dec. 28, 2006

(54) TRANSISTOR COMPONENT

(75) Inventors: MAYK ROEHRICH, Dresden (DE); KLAUS KNOBLOCH, Dresden (DE); ACHIM GRATZ, Dresden (DE)

Correspondence Address: DICKSTEIN SHAPIRO LLP, 1177 AVENUE OF THE AMERICAS 6TH AVENUE, NEW YORK, NY, 10036-2714, US

(73) Assignee: INFINEON TECHNOLOGIES AG, Munich (DE)

(21) Appl. No.: 11/425,821

(22) Filed: Jun. 22, 2006

(30) Foreign Application Priority Data
Jun. 22, 2005 (DE) 102005028905.3

(51) Int. Cl. H01L 29/76

(52) U.S. Cl. 257/370

(57) ABSTRACT

A source connection of a field effect transistor is formed using a contact region, which adjoins a source region, is highly oppositely doped and forms a butting contact with the source region. A well or substrate connecting region which is electrically conductively connected to a supply potential lead is arranged separately from the contact region in the semiconductor material.

### CROSS-REFERENCE TO RELATED APPLICATION

This application claims priority to German Patent Application Serial No. 102005028905.3, which was filed on Jun. 22, 2005 and is incorporated herein by reference in its entirety.

### FIELD OF THE INVENTION

The present invention relates to a transistor component having at least one field effect transistor, in particular a component for electronic logic circuits.

### BACKGROUND OF THE INVENTION

Transistor components may be used to build libraries of electronic circuits which can be respectively combined with one another in an intended manner. Such so-called library cells which may contain, for example, NOR circuits, NAND circuits or similar logic circuits should be protected, if possible, against covert discovery, so-called reverse engineering. In the case of libraries of this type, the circuits may be covered, for example, by electronically and optically nontransparent layer elements. However, such layers may be removed in a relatively simple manner and thus afford only insufficient protection against the covered circuit design being covertly discovered. In addition, concealing the circuit parts which are to be kept secret often requires modification of the production processes which become more expensive as a result. New methods which can be used to design a circuit library in such a manner that reverse engineering is prevented without making the production process considerably more expensive are therefore continually being sought.

The publication by Terrill et al. in IEDM 1984 describes a structure of a connecting contact to doped regions, in which there is arranged, such that it adjoins a region in the semiconductor material which is to be connected and is highly doped for a first conductivity type, a further highly doped region which is, however, doped for the opposite conductivity type. The dopant concentrations are selected to be sufficiently high so that a contact resistance which is sufficiently low for electrical contact is formed at the pn junction. This makes it possible to establish electrical connections between differently doped regions within the semiconductor material. The contact produced at the pn junction is referred to as a butting contact (butted contact).

### SUMMARY OF THE INVENTION

The present invention specifies a transistor component which can be used to build circuit libraries which are protected against reverse engineering.

Transistor structures which are complementary to one another and are arranged in a substrate comprising doped semiconductor material and at least one oppositely doped well which is formed in the latter are provided in the transistor component. The substrate and the at least one well are provided with a highly doped substrate region and with a highly doped well connecting region, respectively, and with a respective associated substrate or well contact. The transistor structures are each field effect transistors having a source region, a drain region and a gate electrode which is arranged such that it is electrically insulated from the semiconductor material via a channel region that is located between the source and the drain. The source region is connected to a supply potential connection, which is implemented using a butting contact (butted contact) in the semiconductor material. A connecting region which is highly doped for this butting contact and is referred to below as a contact region is arranged separately from the well or substrate connecting region within the semiconductor material which is doped for the same conductivity type. Therefore, the well or substrate contact is not used as a connecting region to the source region and is not used to form the butting contact in the source region. Therefore, it is difficult to discern from the transistor structure and the contacts whether or not such a contact region is provided in a respective transistor of the circuit.

When producing the transistor component, the implantations introduced for the purpose of doping can be effected, by means of suitable patternings of the masks used, in such a manner that a plurality of transistor structures are provided and, depending on the circuit to be implemented, the source region of a respective transistor is or is not connected to the supply potential. In this manner, completely different logic circuits can be implemented using configurations, which outwardly appear to be completely identical, of an arrangement of a plurality of actual or apparent transistor structures. It is only possible to ascertain with considerable outlay which source regions of the existing transistor structures are actually connected to the supply potential lead via the substrate or the well and the relevant well or substrate connection and which are not. This configuration can be provided for different types of transistors in respective differently doped semiconductor material, with which the transistors of a CMOS logic circuit may be formed, in particular. It is thus possible to implement different logic circuits of a circuit library (cell library) with an externally identical visual appearance.

### BRIEF DESCRIPTION OF THE DRAWINGS

There follows a more detailed description of examples of the transistor component with reference to the accompanying FIGS. 1 to 5.

FIG. 1 shows part of a plan view of a transistor component according to the prior art.

FIG. 2 shows a plan view in accordance with FIG. 1 for an inventive transistor component.

FIGS. 3A-F use an inverter circuit to show different inventive modifications to a circuit structure which outwardly appears to be the same.

FIG. 4 shows a plan view of an exemplary embodiment for implementing the circuit shown in FIG. 3A.

FIG. 5 shows a plan view in accordance with FIG. 4 of a further exemplary embodiment for implementing the circuit shown in FIG. 3E.

### DETAILED DESCRIPTION OF PREFERRED EMBODIMENTS OF THE INVENTION

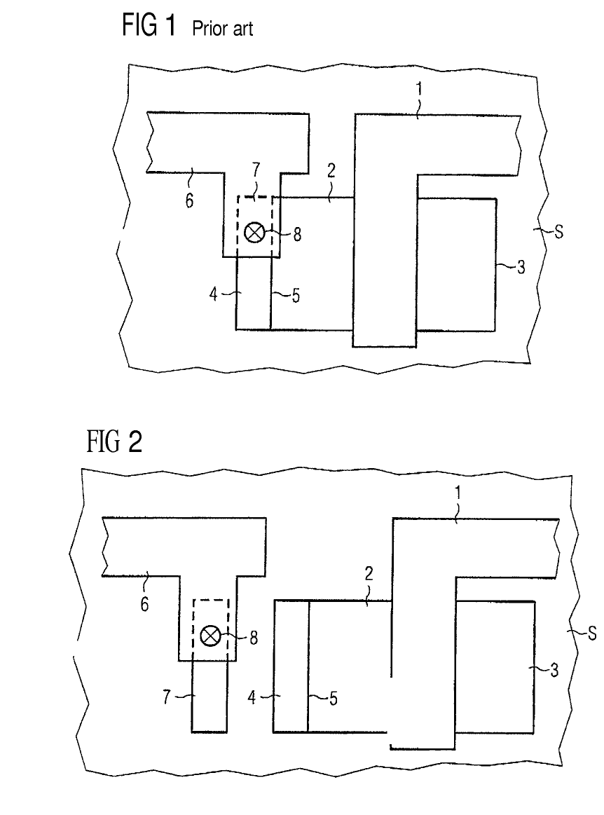

FIG. 1 shows, in part, a plan view of a transistor component according to the prior art. A gate electrode 1, for example comprising polysilicon, together with doped regions for the source and the drain which are formed in the semiconductor material on both sides of said gate electrode are situated on the top side of a substrate S comprising semiconductor material. If the semiconductor material of the substrate is doped in p-conducting fashion, for example, the source region 2 and the drain region 3 are doped in highly n-conducting fashion. A contact region 4 which forms a butting contact 5 for the source region 2 is situated in the semiconductor material such that it adjoins the source region 2. The contact region 4 is highly doped for the conductivity type of the semiconductor material of the substrate, that is to say oppositely to the source region 2; in said example, the contact region 4 is doped in highly p-conducting fashion.

At the same time, the contact region 4 forms a highly doped well or substrate connecting region 7. A lead 6 of a supply voltage connection is preferably patterned on the top side in a metalization plane. A well or substrate contact 8 is provided between this lead 6 and the well or substrate connecting region 7. This connection is used as a well or substrate connection to the relevant supply potential, generally Vdd. In this manner, the well or substrate connecting region and the source region connection are accommodated on the top side of the component in a space-saving manner. The potential of the supply voltage is thus connected both to the well or the substrate and to the source region via the same doped region.

Instead of this, the transistor structure can be arranged in a well which is doped in the opposite manner to the semiconductor material of the substrate S. In the example indicated, this well is doped in n-conducting fashion. The source region 2 and the drain region 3 are then doped in highly p-conducting fashion. In this example, the well contact 8 is situated in a well connecting region 7 which is doped in highly n-conducting fashion, adjoins the source region 2 (which is doped in highly p-conducting fashion) and likewise forms a butting contact 5 at the source.

In contrast to this, a contact region which is separate from the well or substrate connecting region is provided in the inventive transistor component for the electrically conductive connection to the source region. This is illustrated in FIG. 2 which shows part of a plan view in accordance with FIG. 1. The components of the transistor structure which is provided on the substrate S, namely the gate electrode 1, the source region 2 and the drain region 3, correspond to the components from the prior art. A highly doped contact region 4 which forms the butting contact 5 at the source is arranged in this case separately from the well or substrate connecting region 7 at at least a short distance from the well or substrate connecting region 7 and is thus separated from the latter by means of more lightly doped semiconductor material. The well or substrate contact 8 which is used to connect the supply voltage lead 6 to the well or substrate connecting region 7 is situated in a conventional manner in the well or substrate connecting region 7.

The arrangement illustrated in FIG. 2 allows the contact region 4 to be provided or omitted independently of the well or substrate connection which is respectively provided. In accordance with the circuit provided, each individual transistor structure of the component may thus be provided with a source connection or may be limited in a high-impedance manner on the source side. If a multiplicity of transistor structures are provided on the component, entirely different logic circuits which each form part of a circuit library may be implemented by virtue of the source connections being provided via a butting contact or being lacking.

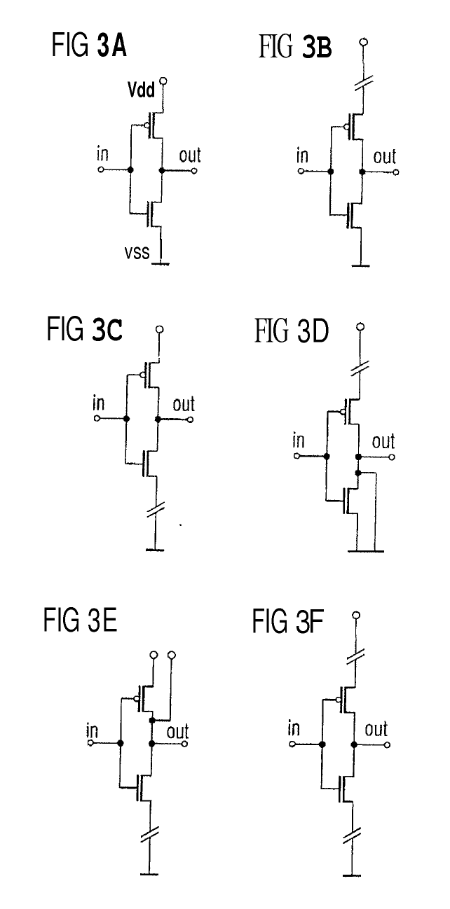

FIG. 3 shows, as examples, the diagrams of circuits which can be implemented according to the invention on the basis of a transistor arrangement which is suitable for an inverter circuit. FIG. 3A illustrates the inverter circuit. Two transistors which are complementary to one another are provided, the gate electrodes of said transistors being connected to one another (input “in”) and the drain connections of said transistors being connected to one another (output “out”). The source connections are respectively connected to one of the supply voltages Vdd or Vss. The source connections of each individual transistor structure may be provided or omitted in the transistor component. If the source connection of the p-channel transistor depicted at the top of FIG. 3A is lacking, the circuit corresponding to FIG. 3B results. If, instead of this, the source connection of the n-channel transistor depicted at the bottom of FIG. 3A is lacking, the circuit shown in FIG. 3C results.

Together with the source region, the drain region may also be connected to the substrate or to the well, preferably likewise using a contact region and a butting contact at the drain region. The circuit shown in FIG. 3D thus results from the circuit shown in FIG. 3B and the circuit shown in FIG. 3E results from the circuit shown in FIG. 3C. Finally, both source connections may also be omitted (corresponding to the circuit diagram shown in FIG. 3F), with the result that the output is terminated in a high-impedance manner on the input side in this case. Starting from any desired transistor circuit, such as the inverter circuit of FIG. 3A indicated in the example, a multiplicity of different logic circuits can thus be implemented by omitting the contact regions which are to be provided for the substrate connection in the implantation step, without this being able to be discerned from the layout of the circuit structure of the component.

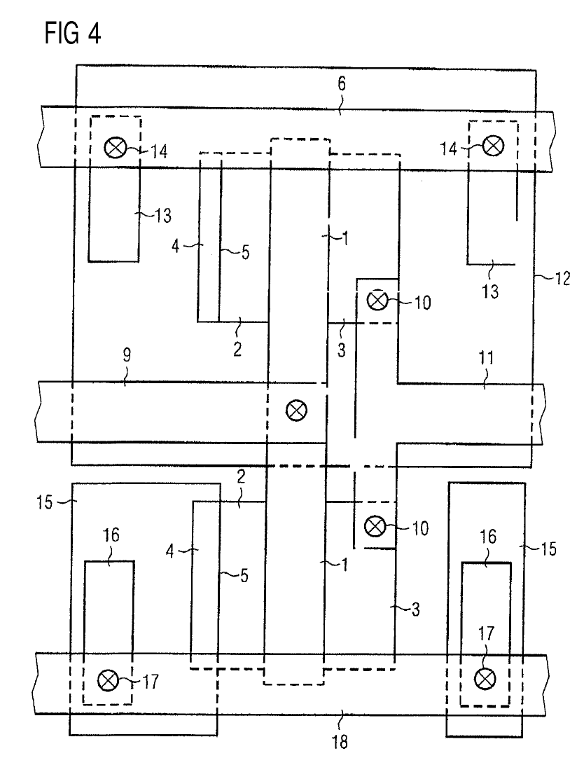

FIG. 4 shows a plan view of transistor structures which can be used to implement the inverter circuit shown in FIG. 3A. The structures illustrated are situated on a substrate comprising semiconductor material which, in the example indicated, is doped in p-conducting fashion. N-channel transistors are formed in this semiconductor material which is doped in p-conducting fashion. In order to produce the p-channel transistors which are complementary to said n-channel transistors, wells 12 which are doped in the opposite manner, that is to say in n-conducting fashion, are produced in the semiconductor material. In the simplified illustration of FIG. 4, the well 12 depicted comprises only the region provided for a p-channel transistor. In general, a plurality of wells which have different sizes and may contain one or more of the transistor structures in question may be provided in components of this type. In the case of complicated arrangements, a plurality of wells which are embedded in one another and are doped in an opposite manner with respect to one another may also be provided in the substrate.

FIG. 4 therefore illustrates, in the upper region, the structure of the p-channel transistor whose source is connected to the supply potential Vdd and, in the lower region, the structure of the n-channel transistor whose source is connected to the other supply potential Vss. Vss is normally the lower potential, usually the ground connection. In this case, the gate electrode 1 is in the form of a strip which preferably comprises polysilicon and runs via both channel regions of the transistors. A gate voltage lead 9 which is formed in a metalization plane and is connected to the gate electrodes via the contact depicted is provided for electrical connection. The source regions 2 of both transistors are connected via contact regions 4 which are arranged such that they adjoin said source regions and form a respective butting contact 5 with the source region. The source region 2 and the drain region 3 of the p-channel transistor which is arranged in the well 12 are each doped in highly p-conducting fashion, that is to say in the opposite manner to the well 12. The source region 2 and the drain region 3 of the n-channel transistor in the semiconductor material of the substrate are doped, in the opposite manner to said substrate, in highly n-conducting fashion. The contact region 4 of the p-channel transistor in the well 12 is therefore doped for the sign of the conductivity of the well 12, that is to say in highly n-conducting fashion, while the contact region 4 of the n-channel transistor in the substrate is doped in highly p-conducting fashion. These contact regions would therefore also be suitable as a well connecting region and a substrate connecting region, respectively.

The special feature of the inventive transistor component is that a separate well connecting region 13 which, in this example, is doped in highly n-conducting fashion is provided for the well 12 and a substrate connecting region 16 which, in this example, is doped in highly p-conducting fashion is provided for the substrate. The well connecting region 13 is connected to the lead 6 of one supply potential (Vdd) via the well contact 14, while the substrate connecting region 16 is connected to the other supply potential (ground lead 18) via the substrate contact 17. FIG. 4 depicts two respective well connecting regions 13 and substrate connecting regions 16 which is preferred but not necessary. The drain regions 3 are each connected to the output line 11 via drain contacts 10. It can only be detected with difficulty where a contact region or else both contact regions has/have been omitted in this arrangement. In addition, a corresponding contact region may also be provided on the side of the drain region 3.

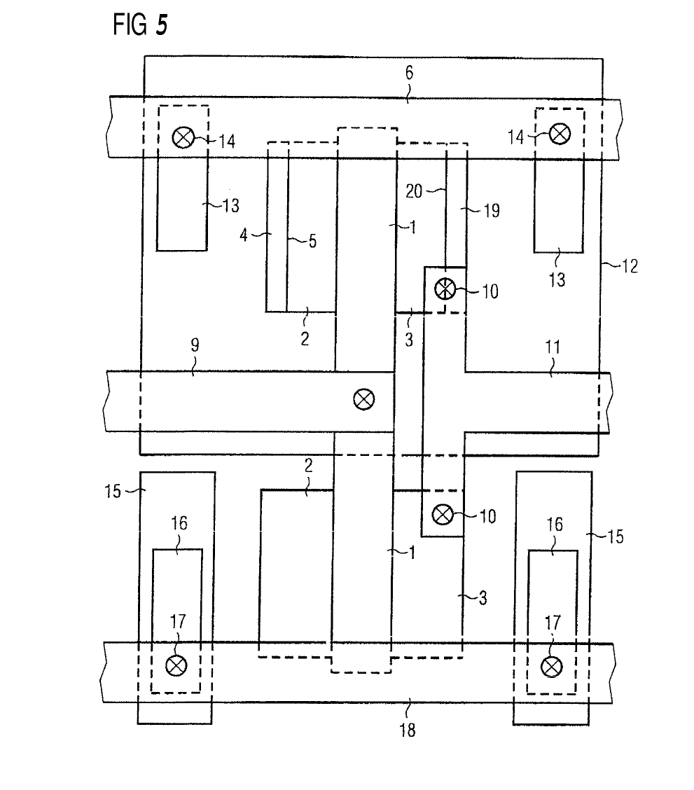

FIG. 5 shows a plan view (corresponding to FIG. 4) of the circuit shown in FIG. 3E. In this case, the p-channel transistor in the well 12 has another contact region 19 which forms a butting contact 20 at the drain. In the exemplary embodiment illustrated, the drain contact 10 is applied both to the drain region 3 and to the relevant contact region 19. However, it suffices for the drain contact 10 to be applied only to the drain region 3 since the drain region 3 is connected to the potential of the well via the butting contact 20 and the contact region 19. In this case, the source and drain are thus shorted together.

The well 12 is produced using a suitable mask by means of n-implantation. An n⁺-implantation using a further mask is used to produce the contact regions 4, 19 of the p-channel transistor and the well connecting regions 13 as well as the source region and the drain region of the n-channel transistor. A p⁺-implantation is used to produce the source region 2 and the drain region 3 of the p-channel transistor which is arranged in the well 12 as well as the substrate connecting regions 16. In the example illustrated in FIGS. 4 and 5, the substrate connecting regions 16 are situated in a region 15, which is doped in highly p-conducting fashion, in the substrate. However, the dimensions of these regions are, in principle, optional. The patterned layers of polysilicon, metalization planes and contact vias are arranged in accordance with conventional transistor components, so that the modification to the different circuits results from the presence or absence of the butting contacts. Only the masks of the n⁺-implantations and p⁺-implantations need to be changed.

What is claimed is:

1. A transistor component comprising:
a substrate having semiconductor material which is doped for a first conductivity type;
at least one well, which is arranged on a main side of the substrate and is doped for a second opposite conductivity type;
at least one structure of a field effect transistor, said structure being formed in the substrate inside or outside the well and having a gate electrode, a source region and a drain region, the gate electrode being arranged above a channel region which is provided between the source region and the drain region and being electrically insulated from the semiconductor material, and the source region and the drain region being highly doped for the conductivity type that is opposite to that of the channel region;
at least one well or substrate connecting region, which is arranged in the substrate inside or outside the well and is highly doped for the conductivity type of the surrounding semiconductor material;
a well or substrate connecting contact, which is arranged in the well or substrate connecting region and is provided electrically conductively connecting the well or substrate connecting region to a supply voltage lead;
an electrical connection between the supply voltage lead and the source region;
a contact region, which adjoins the source region, is highly doped for the conductivity type that is opposite to that of the source region, and is separated from the well or substrate connecting region by a more lightly doped semiconductor material; and
a butting contact provided between the contact region and the source region.

2. The transistor component as claimed in claim 1, further comprising structures of field effect transistors which are complementary to one another provided both inside and outside the well, and
wherein each connection of a source region of one of the field effect transistors to the supply voltage lead is provided using a respective contact region, which adjoins the relevant source region, is highly doped for the conductivity type that is opposite to that of the source region, forms a butting contact with the source region, and forms a well or substrate connecting region, which is highly doped for the same conductivity type as the contact region.

3. The transistor component as claimed in claim 2, further comprising at least one further transistor structure, the source region of which is not connected to a supply voltage lead.

4. The transistor component as claimed in claim 1, further comprising a first transistor structure and a second transistor structure, which is complementary to the first transitor structure,
wherein the first and second transistor structures have a common connection of the gate electrodes and a common connection of the drain regions, and at least one of the first and second transistor structures has a source region which is not connected to a supply voltage lead.

5. The transistor component as claimed in claim 4, wherein one of the first and second transistor structures has a further contact region, which is arranged to adjoin the respective drain region, is highly doped for the conductivity type that is opposite to that of the drain region, and forms a further butting contact with the drain region.

6. A transistor component comprising:
a substrate having semiconductor material;
a source region formed in the semiconductor material;
a contact region, which adjoins the source region, and is highly oppositely doped from the source region and forms a butting contact with the source region; and
a well or substrate connecting region, which is electrically conductively connected to a supply potential lead, arranged separately from the contact region in the semiconductor material.
